(19) United States
(12) Patent Application Publication
(10) Pub. No.: US 2026/0191102 A1
(43) Pub. Date: Jul. 2, 2026

(54) PACKAGE STRUCTURE, APPARATUS, AND METHOD FOR PREPARING THE SAME

(71) Applicant: Yangtze Memory Technologies Co., Ltd., Wuhan, Hubei (CN)

(72) Inventors: Ping MO, Wuhan (CN); Li TAO, Wuhan (CN); Peng CHEN, Wuhan (CN); Hongqing PAN, Wuhan (CN)

(21) Appl. No.: 19/373,684

(22) Filed: Oct. 29, 2025

(30) Foreign Application Priority Data
Dec. 27, 2024 (CN) 202411958963.2

(51) Int. Cl. H01L 23/00; H01L 25/065

(52) U.S. Cl. CPC H10W 90/00; H10W 72/072; H10W 72/073; H10W 72/241; H10W 72/859; H10W 72/865; H10W 72/879; H10W 72/884; H10W 72/926; H10W 72/944; H10W 74/15; H10W 90/24; H10W 90/722; H10W 90/724; H10W 90/732; H10W 90/734; H10W 90/754

(57) ABSTRACT

Implementations provide package structures, apparatuses, and methods for preparing the same. In an implementation, a package structure comprises: a mounting substrate; a first die disposed above the mounting substrate, the first die comprising a first main surface, a second main surface opposite to the first main surface, and an active device formed adjacent to the first main surface; and a second die interposed between the first die and the mounting substrate, wherein the first main surface of the first die faces towards the second die.

### CROSS-REFERENCE TO RELATED APPLICATIONS

This application claims priority to Chinese Patent Application No. 202411958963.2, filed on Dec. 27, 2024, which is hereby incorporated by reference in its entirety.

### TECHNICAL FIELD

The present disclosure relates to package structures, apparatuses, and methods for preparing the same.

### BACKGROUND

Stacks of chips (or dies) are widely used for various electronic products. As the electronic products trend to have a low profile, the package therefor, for example, package of the stack of chips, trends to have a reduced thickness meanwhile still meets the high mechanical strength requirement for the stack of chips, such as for example the stack of memory chips.

With the increase of the number of layers in the memory chip, the proportion of silicon in the chip continues to decrease, and thus it may be difficult to continue to improve the strength of the circuit side (e.g., circuit layer) of the chip. Thus, when the circuit side encounters compress or stress, there may be a potential risk that cracks or defects may be adversely induced.

### SUMMARY

According to an aspect of the present disclosure, a package structure is provided that comprises: a mounting substrate; a first die disposed above the mounting substrate, the first die comprising a first main surface, an opposite second main surface and an active device formed adjacent to the first main surface; and a second die interposed between the first die and the mounting substrate, wherein the first main surface of the first die faces towards the second die.

In an implementation, the first die comprises a first coupling component provided in or on the first main surface, the second die comprises a first main surface, an opposite second main surface and a second coupling component provided in or on one of the first main surface and the second main surface of the second die facing the first die, and the first coupling component is connected to the second coupling component via a solder bump or a metal pillar.

In an implementation, the package structure further comprises: an encapsulant at least encapsulating the first die and the second die.

In an implementation, the first die further comprises: a Redistribution Layer (RDL) at the second main surface of the first die.

In an implementation, the second die further comprises an active device formed adjacent to the first main surface of the second die, the first main surface of the second die faces towards the mounting substrate, and the second coupling component is provided in or on the second main surface of the second die.

In an implementation, the second die further comprises an active device formed adjacent to the first main surface of the second die, the first main surface of the second die faces towards the first die, and the second coupling component is provided in or on the first main surface of the second die.

In an implementation, the second die further comprises a Redistribution Layer (RDL) formed adjacent to the main surface of the second die and wherein the second coupling component comprises a pad positioned in the Redistribution Layer (RDL).

In an implementation, the package structure further comprises: a wire having one end coupled to the second coupling component and the other end coupled to the mounting substrate.

In an implementation, the package structure further comprises: an insulating bonding layer interposed between the first and second dies, wherein the solder bump or a metal pillar is at least partly disposed in the insulating bonding layer.

In an implementation, the package structure further comprises: a stack structure comprising a plurality of dies and disposed over the mounting substrate, and an encapsulant at least encapsulating the stack structure of the plurality of dies, wherein, each of the plurality of dies comprises a first main surface with an active device formed adjacent to the first main surface and an opposite second main surface, the plurality of dies at least comprises the first die and the second die and at least a third die, wherein the first die is the furthest die of the stack structure from the mounting substrate, and the second die is a die immediately adjacent to the first die in the stack structure, and wherein respective first main surfaces of the plurality of dies face towards the mounting substrate.

In an implementation, the plurality of dies are substantially the same as each other.

In an implementation, the package structure further comprises: at least one third die disposed between the second die and the mounting substrate.

In an implementation, the first die comprises a memory die.

According to another aspect of the present disclosure, an apparatus is provided that comprises: a board; and a package structure mounted over the board, the package structure comprising: a mounting substrate; a first die disposed above the mounting substrate, the first die comprising a first main surface, an opposite second main surface and an active device formed adjacent to the first main surface; and a second die interposed between the first die and the mounting substrate, wherein the first main surface of the first die faces towards the second die.

According to a further aspect of the present disclosure, a method for preparing a package structure is provided. The method comprises: providing a mounting substrate; mounting a plurality of dies at least comprising a first die and a second die over the mounting substrate with the second die interposed between the first die and the mounting substrate, the first die comprising a first main surface, an opposite second main surface and an active device formed adjacent to the first main surface, wherein the first die is mounted over the second die with the first main surface of the first die facing towards the second die.

In an implementation, the first die comprises a first coupling component provided in or on the first main surface, and the second die comprises a second coupling component provided in or on a main surface of the second die facing the first die. In an implementation, mounting a plurality of dies over the mounting substrate comprises: mounting the second die over the substrate; and mounting the first die over the second die with the first main surface of the first die facing towards the second die, including: coupling the first coupling component of the first die to the second coupling component of the second die; and attaching the first die to the second die with insulating bonding layer interposed between the first and second dies.

In an implementation, the plurality of dies further comprises at least one third die, the first die comprises a first coupling component provided in or on the first main surface, the second die comprises a second coupling component provided in or on a main surface of the second die facing the first die, and mounting the plurality of dies over the mounting substrate comprises: mounting the at least one third die over the mounting substrate; and mounting the second die over the at least one third die; and mounting the first die over the second die with the first main surface of facing towards the second die, including: coupling the first coupling component of the first die to the second coupling component of the second die via a solder bump or a metal pillar; and attaching the first die to the second die with insulating bonding layer interposed between the first and second dies.

In an implementation, the method further comprises: bonding at least one wire between the second die and the mounting substrate; and applying an encapsulant to at least encapsulate the plurality of dies.

In an implementation, the first die is the furthest die of the plurality of dies from the mounting substrate.

In an implementation, each of the plurality of dies comprises a first main surface with active devices formed adjacent to the first main surface and an opposite second main surface, and comprises a first coupling structure at the first main surface thereof and a Redistribution Layer (RDL) at the second main surface thereof, the first coupling structure including a first coupling component provided in or on the first main surface. In an implementation, the method further comprises: providing a semiconductor wafer which at least comprises semiconductor substrates of and the respective first coupling structures of the first die and the second die; forming solder bumps or metal pillars at desired positions (e.g., bond pad area) of the semiconductor wafer, to be coupled to corresponding first coupling components of the first die and the second die; thinning the semiconductor wafer from a side of the semiconductor wafer opposite to the solder bumps or metal pillars; forming, after the thinning, at least the RDLs of the first and second dies on the side of the semiconductor wafer opposite to the solder bumps or metal pillars; and singulating the semiconductor wafer to form at least the first die and second die. Other features of the present disclosure and advantages thereof will become apparent from the following detailed description of exemplary implementations of the present disclosure with reference to the accompanying drawings.

### BRIEF DESCRIPTION OF THE DRAWINGS

The accompanying drawings, which are incorporated in and constitute a part of this specification, illustrate implementations of the present disclosure and together with the description, serve to explain the principles of the disclosure.

The present disclosure may be more clearly understood from the following detailed description taken in conjunction with the accompanying drawings, in which:

FIG. 1 shows a schematic sectional view of an example package structure;

FIG. 2 shows a schematic sectional view of a package structure according to an implementation of the present disclosure;

FIGS. 3A, 3B and 3C each show a schematic sectional view of a die according to an implementation of the present disclosure;

FIG. 4 shows a schematic sectional view of a package structure according to an implementation of the present disclosure;

FIG. 5A shows a schematic sectional view of a package structure according to an implementation of the present disclosure;

FIG. 5B shows a schematic sectional view of a package structure according to an implementation of the present disclosure;

FIG. 6A shows a schematic sectional view of a package structure according to an implementation of the present disclosure;

FIG. 6B shows a schematic sectional view of a package structure according to an implementation of the present disclosure;

FIG. 7 shows a schematic sectional view of a package structure according to an implementation of the present disclosure;

FIG. 8A shows a flow chart of a method of preparing a package structure according to an implementation of the present disclosure;

FIGS. 8B and 8C each show a flow chart of a method of mounting a plurality of dies over the mounting substrate according to implementations of the present disclosure;

FIG. 9 shows a flow chart of a method of preparing a package structure according to an implementation of the present disclosure; and

FIG. 10 shows an apparatus comprising a package structure according to an implementation of the present disclosure.

Note that in the implementations described below, the same reference numerals are used in common between different drawings to denote the same portions or portions having the same functions, and a repetitive description thereof will be omitted. In this specification, like reference numerals and letters are used to designate like items, and therefore, once an item is defined in one drawing, further discussion thereof is not required in subsequent drawings.

For convenience of understanding, the positions, dimensions, ranges, and the like of the respective structures shown in the drawings and the like do not necessarily indicate actual positions, dimensions, ranges, and the like. The orientations shown in the drawings are merely illustrative. Therefore, the present disclosure shall not be limited to the positions, orientations, dimensions, ranges, etc. disclosed in the drawings and the like.

### DETAILED DESCRIPTION OF THE EMBODIMENTS

Various exemplary implementations of the present disclosure will now be described in detail with reference to the accompanying drawings. However, one skilled in the relevant art will recognize that implementations may be practiced without one or more of these specific details, or with other methods, components, materials, etc. It should be noted that the relative arrangement of parts and steps, numerical expressions and numerical values set forth in these implementations are not intended to limit the scope of the present disclosure unless expressly stated otherwise. Additionally, techniques, methods, and apparatus known to one of ordinary skill in the relevant arts may not be discussed in detail but are intended to be part of the specification where appropriate.

It should be understood that the following description of at least one exemplary implementation is merely illustrative and is not intended to limit the disclosure, its application, or uses. It should also be appreciated that any implementation described exemplarily herein does not necessarily indicate that it is preferred or advantageous over other implementations. The disclosure is not limited by any expressed or implied theory presented in the preceding technical field, background, summary or the detailed description.

In addition, certain terminology may also be used in the following description for the purpose of reference only, and is thus not intended to be limiting. For example, the terms “first,” “second,” and other such numerical terms referring to structures or elements do not imply a sequence or order unless clearly indicated by the context.

It will be further understood that the terms “comprises” and/or “comprising”, when used herein, specify the presence of stated features, integers, steps, operations, elements, and/or components, but do not preclude the presence or addition of one or more other features, integers, steps, operations, elements, components, and/or groups thereof.

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly indicates otherwise.

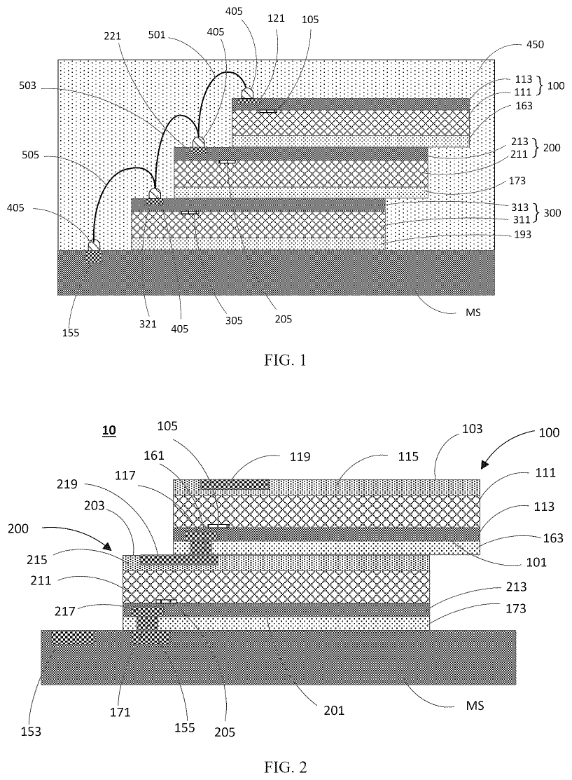

FIG. 1 shows a schematic sectional view of an example package structure. As shown in FIG. 1, the package structure includes a mounting substrate MS and a stack structure of dies disposed over the mounting substrate. The stack structure of dies may include at least two dies. There, the stack structure is illustrated as including a first die 100, a second die 200 and a third die 300 disposed over the mounting substrate MS.

Each die may include a substrate, e.g., semiconductor substrate, and a circuit layer over the substrate. The circuit layer may include one or more insulating layers and one or more conductive layers (for example, metal layers) formed on or in the respective insulating layers for providing connections to the semiconductor substrate, for example, to the active devices formed on or in the semiconductor substrate.

As shown in FIG. 1, the first die 100 may include a semiconductor substrate 111 with a circuit layer 113 formed over the semiconductor substrate 111. In some implementations, the semiconductor substrate may be formed from for example but not limited to, silicon substrate or Silicon on Insulator (SOI) substrate. In some implementations, the semiconductor substrate may include one or more layers of other materials, such as polysilicon, dielectric materials, or metal or other conductive materials. While the semiconductor substrate may be shown as a single layer in the drawings, one skilled in the art would readily appreciate that in practice the semiconductor substrate may include multiple layers.

Active device(s) 105, such as transistors, memory cells, etc. may be formed on or in a first surface of the semiconductor substrate 111 close to the circuit layer. The circuit layer 113, for example, may include one or more insulating layers and one or more conductive layers (for example, metal layers) formed on or in the respective insulating layers for providing connection to the semiconductor substrate 111, for example, to the active devices formed on or in the semiconductor substrate 111. The conductive layer may form a wiring, a pad, an electrode, a contact, a via and/or the like. As an example, a coupling component (e.g. pad) 121 is shown; however, this is only illustrative, and there can be more or other coupling components 121 in practice.

The dies 200 and/or 300 can be configured the same as or similar to the first die 100. The second die 200 may include a semiconductor substate 211 with a circuit layer 213 formed over the semiconductor substrate 211. Active device(s) 205 may be formed on or in a surface of the semiconductor substrate 211 adjacent to the circuit layer. The third die 300 may include a semiconductor substate 311 with a circuit layer 313 formed over the semiconductor substrate 311. Active device(s) 205 or 305 may be formed on or in a surface of the semiconductor substrate 211 or 311 adjacent to the respective circuit layer 213 or 313. Similarly, the circuit layer 213/313 may include one or more insulating layers and one or more conductive layers (for example, metal layers) formed on or in the respective insulating layers for providing connection to the semiconductor substrate 211/311, for example, to the active devices formed on or in the respective semiconductor substrate. Similarly, a coupling component (e.g. pad) 221 is shown in the circuit layer 213 of the second die 200, and a coupling component (e.g. pad) 321 is shown in the circuit layer 313 of the third die 300.

The first die 100 may be attached to the second die 200 via an insulating bonding layer 163, for example, Die Attach Film (DAF) or epoxy, polyimide, etc. The second die 200 may be attached to the third die 300 via an insulating bonding layer 163. The third die 300 may be attached to the mounting substrate MS with an insulating bonding layer 173.

The package structure may further include bonding wires 501, 503, 505 for being bonded with the mounting substrate MS and the dies respectively, for example, with solder bumps or solder paste 405. The package structure may further include an encapsulant 450 which at least encapsulate the dies and the bonding wires.

In this example, the front surfaces (i.e., circuit layer side) of the dies (e.g., the first die 100) are arranged upwards with respect to the mounting substrate. However, in such case, when the package structure encounters compressing or pressures in manufacturing, shipping, or in use, etc., there may be a risk of functional failure of the dies under strain or stress at least partially due to the relatively weak joint point(s) between different materials/layers.

FIG. 2 shows a schematic sectional view of a package structure according to an implementation of the present disclosure. As shown in FIG. 2, the package structure 10 includes a mounting substrate MS and a stack structure of dies disposed over the mounting substrate. The stack structure of dies may at least include a first die 100 disposed above the mounting substrate MS, and a second die 200 interposed between the first die 100 and the mounting substrate MS.

The first die 100 has a first main surface 101 with active devices formed adjacent to the first main surface 101 and an opposite second main surface 103. As shown in FIG. 2, the first die 100 is stacked with the second die 200, with the first main surface 101 of the first die 100 facing towards the second die 200.

In some implementations, the first die 100 may be a memory die which has memory cells, for example, NAND cells, DRAM cells, SRAM cells, and/or the like; however the present disclosure shall not be limited thereto. In some implementations, the second die 200 can be a memory die with memory cells too, for example, memory cells of the same type of the memory cells of the first die 100. Alternatively, the second die 200 may be not a memory die, for example, may be a logic die, a controller die, or a dummy die; in other words, the second die 200 may be of a different type from that of the first die.

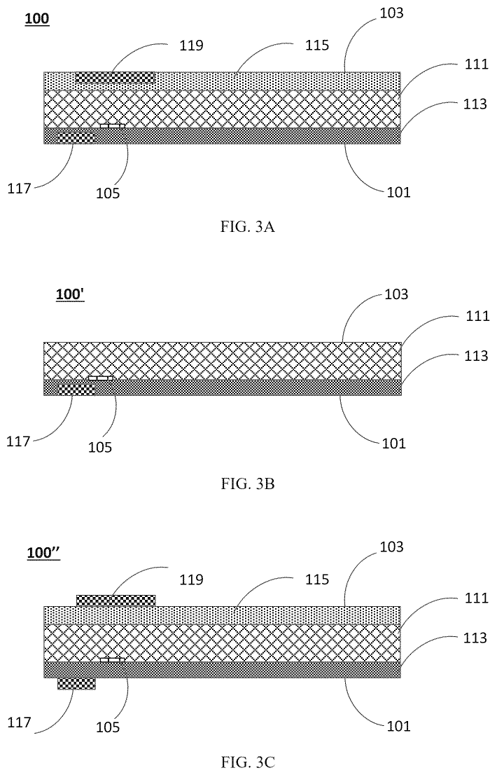

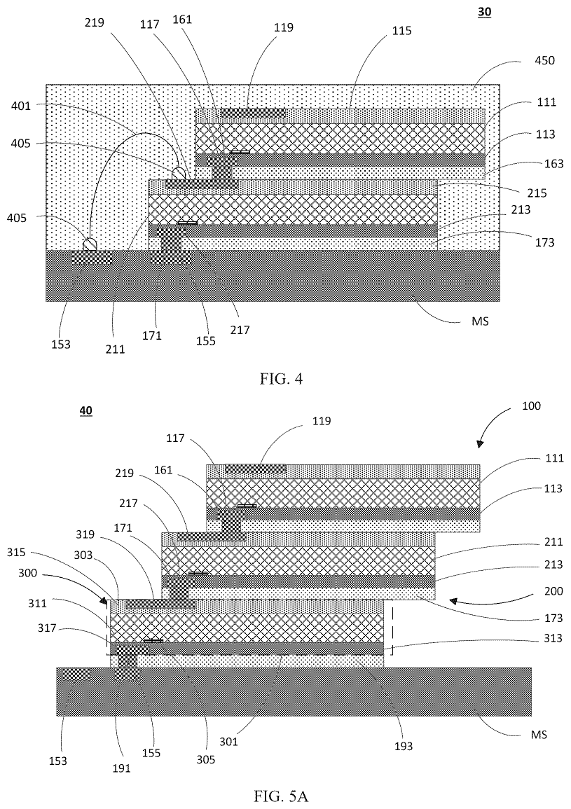

FIGS. 3A, 3B, and 3C each show a schematic sectional view of a die according to an implementation of the present disclosure. Here, description is given with the first die 100 as an example, and can be similarly or adaptively applied to other dies when appropriate. Like references are used to indicate like elements in the drawings.

As shown in FIG. 3A, the die (e.g., first die 100) may include a semiconductor substrate 111 with a circuit layer 113 formed on a first surface of the semiconductor substrate 111 (i.e., the lower surface thereof in the orientation of FIG. 3A). In one implementation, the semiconductor substrate may include silicon. However, the substrate can include other types of semiconductor materials. In some implementations, the semiconductor substrate may be formed from for example but not limited to, silicon substrate or Silicon on Insulator (SOI) substrate. In some implementations, the semiconductor substrate may include one or more layers of other materials, such as polysilicon, dielectric materials, or metal or other conductive materials. While the semiconductor substrate may be shown as a single layer in the drawings, one skilled in the art would readily appreciate that in practice the semiconductor substrate may include multiple layers.

Active device(s) 105, such as transistors, memory cells, etc. may be formed on or in the first surface 101 of the semiconductor substrate 111. The circuit layer 113, for example, may include one or more insulating layers and one or more conductive layers (for example, metal layers) formed on or in the respective insulating layers for providing connection to the semiconductor substrate 111, for example, to the active devices formed on or in the semiconductor substrate 111. The conductive layer may form a wiring, a pad, an electrode, a contact, a via and/or the like. As an example, a coupling component (e.g. pad) 117 is shown; however, this is only illustrative, and there can be more coupling components 117 in practice. Those skilled in the art would readily understand that the pad 117 may be coupled to the substrate 111 or to the devices formed in or on the substrate 111 through other conductive layer, via, contact, or any combination thereof (not shown).

In some implementations, the first die 100 may further includes a interconnection layer (e.g., a redistribution layer (RDL)) 115 on a second surface, opposite to the first surface, of the semiconductor substrate 111, as shown in FIG. 3A. The RDL 115 may include a coupling component (e.g., pad) 119 which may be formed on or embedded in an insulating layer (not labelled). Here, in the implementation of FIG. 3A, the surface of the circuit layer 113 which faces away from the substrate 111 constitutes the first main surface 101 of the first die 100. Meanwhile, the surface of the RDL 115 which faces away from the substrate 111 constitutes the second main surface 103 of the first die 100, which is opposite to the first main surface 101. Please note that the structure 115 in the first die of this implementation may serve as a dummy layer or a buffer layer, which may not function electrically.

In some other implementations, such interconnection layer (e.g., the RDL) 115 may be not present. FIG. 3B shows a schematic sectional view of a die 100′ according to another implementation of the present disclosure. The die 100′ as shown in FIG. 3B differs from the die 100 as shown in FIG. 3A in that it does not include the RDL on the second surface of the semiconductor substrate 111 (i.e., the upper surface thereof). In such a case, the second surface of the semiconductor substrate 111 constitutes the second main surface 103 of the die 100′. FIG. 3C shows a schematic sectional view of a die 100″ according to an implementation of the present disclosure. The die 100″ shown in FIG. 3C differs from the die 100 shown in FIG. 3A in that the coupling component (e.g., pad) 117 is shown as being formed on the surface of the circuit layer, while the coupling component (e.g., pad) 119 is shown as being formed on the surface of the RDL layer 115.

Now, back to FIG. 2, the second die 200 can be configured the same as or similar to the first die 100. As shown in FIG. 2, similarly, the second die 200 may include a semiconductor substate 211 with a circuit layer 213 formed on a first surface (e.g., the lower surface thereof in the orientation of FIG. 2) of the semiconductor substrate 211. Active device(s) 205 may be formed on or in the first surface of the semiconductor substrate 211. The circuit layer 213, for example, may include one or more insulating layers and one or more conductive layers (for example, metal layers) formed on or in the respective insulating layers for providing connection to the semiconductor substrate 211, for example, to the active devices formed on or in the semiconductor substrate 211. The conductive layer may form a wiring, a pad, an electrode, a contact, a via and/or the like. As an example, a coupling component (e.g. pad) 217 is shown; however, this is only illustrative, and there can be more coupling components 217 in practice. Those skilled in the art would readily understand that the pad 217 may be coupled to the substrate 211 or to the devices formed in or on the substrate 211 through other conductive layer, via, contact, or any combination thereof (not shown). In some other implementations, the second die can be configured differently from the first die.

As shown in FIG. 2, the first die 100 may include a first coupling component (e.g., pad) 117 provided in or on the first main surface 101 thereof. The second die 200 may include a second coupling component provided in or on a main surface 203 of the second die 200 facing the first die 100. In some implementations, the coupling component 117 of the first die 100 may be coupled to the coupling component 219 of the second die 200, for example, via a solder bump or metal pilar 161. Further, an insulating bonding layer 163 can be formed between the first die 100 and the second die 200. In an implementation, the insulating bonding layer 163 is adhesive so as to facilitate securing the first die and the second die with each other. As an example, the insulating bonding layer 163 may be formed from, for example, Die Attach Film (DAF) or epoxy, polyimide, etc. The solder bump or metal pillar 161 may be at least partly disposed in the insulating bonding layer 163.

In some implementations, the second die 200 may be mounted onto the mounting substrate MS. As an example, the mounting substate MS may be a Printed Circuit Board or any other substrate suitable for mounting IC dies. The coupling component 217 of the second die 200 may be connected to a corresponding coupling component (e.g., pad or conductive trace) 155 of the mounting substrate MS, for example, through a solder bump or metal pillar 171. The mounting substrate MS may include additional coupling components (e.g. pad or conductive trace) 153, for example, for wire bonding as will be described later. The second die 200 may be attached to the mounting substrate MS with an insulating bonding layer 173, for example, formed, for example, Die Attach Film (DAF) or epoxy, polyimide, etc. In an implementation, the insulating bonding layer 163 is adhesive. The solder bump or metal pillar 171 may be at least partly disposed in the insulating bonding layer 173. Please note that the geometries of the insulating bonding layers 163 and 173 are just illustrative and not for limiting purpose, and can be widely changed according to the materials and processes used therefor.

In the implementation shown in FIG. 2, the second die 200 is disposed such that the first main surface of the second die 200 faces towards the mounting substrate MS too. In other implementations, the second die 200 can be disposed differently, for example, the first main surface of the second die 200 may face towards the first die, which will be described later.

Further, in some other implementations, there may be other dies interposed between the second die 200 and the mounting substrate MS. Although FIG. 2 shows a package structure has a stack structure of two dies, in some other implementations, the package structure may include more than two dies, for example, 3, 4, 5, 6, 7, or 8 dies, or even more. These numbers are merely illustrative, and the number of the dies comprised in the package structure can be selected according to requirements of the detailed applications. According to various implementations, at least an upper portion or all of the dies are positioned “reversely”, that is, the first main surfaces of this portion of dies or of all the die face towards the mounting substrate.

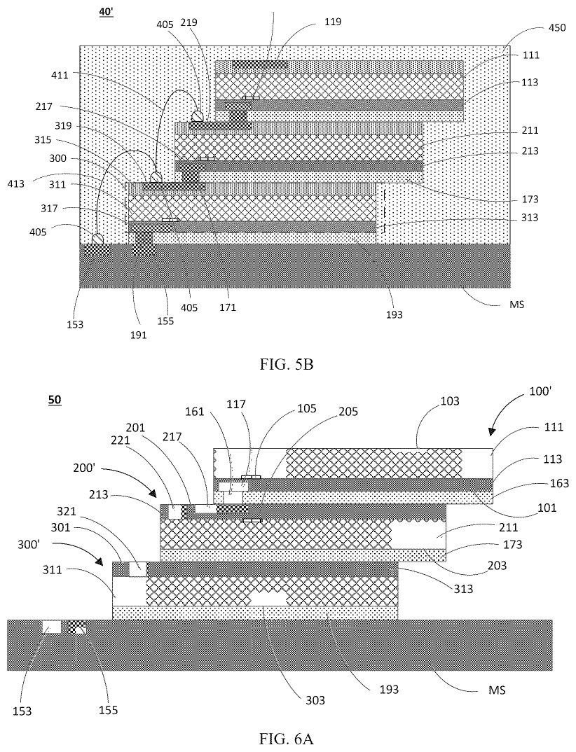

In some implementations, there may be at least one third die (for example, the third die 300 as shown in FIGS. 5A and 5B) disposed between the second die 200 and the mounting substrate MS. In an implementation, the first die 100 is the furthest die in the stack structure away from the mounting substrate.

FIG. 4 shows a schematic sectional view of a package structure according to an implementation of the present disclosure. Those elements which are the same as those illustrated and described in FIGS. 2, 3A and 3B will be designated with same references and will be omitted from being described in detail.

The structure shown in FIG. 2 is further bonded with wire(s) and encapsulated, resulting in the package structure 30 as shown in FIG. 4. In addition to the structure 100 shown in FIG. 2, the package structure 30 includes a wire 401 for being bonded with the mounting substrate MS and the second die 200 respectively. As an example, the wire 401 has one end coupled to the coupling component 219 of the second die 200 and the other end coupled to the coupling component 153 of the mounting substrate MS, for example, with solder bumps or solder paste 405 or with any other suitable means.

The package structure 30 may further include an encapsulant 450 which at least encapsulate the plurality of dies including the first die 100 and the second die 200. In an implementation, the encapsulant 450 also encapsulate the wire 401 as well. As the encapsulant 450, various materials can be employed, for example but not limited to, epoxy, polyimide, etc.

FIG. 5A shows a schematic sectional view of a package structure 40 according to an implementation of the present disclosure. The package structure 40 differs from the package structure 10 in that, in addition to the first die 100 and the second die 200, the package structure 40 further includes at least one third die 300 interposed between the second die 200 and the mounting substrate MS, and that the second die 200 is stacked over the at least one third die 300 which is mounted onto the mounting substrate MS. Although only one third die 300 is illustrated in FIG. 5A, those skilled in the art would readily understand that there can be more third dies interposed between the second die 200 and the mounting substrate MS, and the coupling of those additional third dies therebetween and the with the second die and the mounting substrate MS are within the capability of the those skilled in the art on bases of the implementations and principles disclosed herein. The descriptions as above in connection with the first die 100 and the second die can be likewise or adaptively applied to the third die 300 if needed, according to some implementations.

In this implementation of FIG. 5A, the third die 300 may be the same as or have the same or similar structure as the first die 100 and/or the second die 200. For example, the dies can be manufactured with the same design of circuitries, same layouts, and same processes. In some other implementations, however, the third die 300 may be different from the first die 100 or the second die 200. In some implementations, for example, the first die 100 may be a memory die with memory cells, and either of the second die 200 and the third die may be a memory die, a controller or logic die, or a dummy die.

As can be seen from FIG. 5A, the third die 300 may include a semiconductor substrate 311 with a circuit layer 313 formed on a first surface of the semiconductor substrate 311 (i.e., the lower surface thereof, in the orientation of FIG. 5A). Active device(s) may be formed on or in the first surface of the semiconductor substrate 311. The circuit layer 313, for example, may include one or more insulating layers and one or more conductive layers (for example, metal layers) formed on or in the respective insulating layers for providing connection to the semiconductor substrate 311, for example, to the active devices formed on or in the semiconductor substrate 311. The conductive layer may form a wiring, a pad, an electrode, a contact, a via and/or the like. As an example, a coupling component (e.g. pad) 317 is shown; however, this is only illustrative, and there can be more coupling components 317 in practice. Those skilled in the art would readily understand that the pad 317 may be coupled to the substrate 311 or to the devices formed in or on the substrate 311 through other conductive layer, via, contact, or any combination thereof (not shown).

In some implementations, the third die 300 may further includes a interconnection layer (e.g., redistribution layer (RDL)) 315 on a second surface, opposite to the first surface, of the semiconductor substrate 311, as shown in FIG. 5A. The interconnection layer 315 may include a coupling component (e.g., pad) 319 which is formed on or embedded in an insulating layer (not labelled). Here, in the implementation of FIG. 5A, the surface of the circuit layer 313 which faces away from the substrate 311 constitutes the first main surface 301 of the third die 300. Meanwhile, the surface of the RDL 315 which faces away from the substrate 311 constitutes the second main surface 303 of the third die 300, which is opposite to the first main surface 301. In another implementation, the RDL 315 may be not necessary.

In this implementation, the third die 300 is mounted onto the mounting substrate 300. In an implementation, the coupling component 317 of the third die 300 is connected to the coupling component 155 of the mounting substrate MS via, for example, solder bump or metal pillar 191, and an insulating bonding layer 193 may be formed between the third die 300 and the mounting substrate so as to facilitate the securing of the third die 300 to the substrate MS. The solder bump or metal pillar 191 may be at least partly disposed in the insulating bonding layer 163.

In this implementation, the third die 300 is mounted such that the first main surface 301 (lower surface, in FIG. 5A) of the third die 300 faces towards to the mounting substrate MS. In other implementations, the third die 300 can be configured such that the second main surface 303 of the third die 300 faces towards to the mounting substrate MS, instead. In such a case, the interconnection layer (e.g., RDL) 315 may be not present.

FIG. 5B shows a schematic sectional view of a package structure 40′ according to an implementation of the present disclosure. in addition to the package structure 40, the package structure 40′ further includes a wire 411 for bonding with the second die 200 and the third die 300 respectively, and a wire 413 for bonding with the mounting substrate MS and the third die 300 respectively. In an implementation, the wire 411 has one end coupled to the coupling component 219 of the second die 200 and the other end coupled to the coupling component 319 of the third die 300 and thus to the wire 413, for example, with solder balls or solder paste 405 or with any other suitable means. The wire 413 has one end coupled to the coupling component 319 of the third die 300 and the other end coupled to the coupling component 153 of the mounting substrate MS, for example, with solder balls or solder paste 405 or with any other suitable means. Also, the package structure 40′ may include an encapsulant 450 which at least encapsulate the stack structure of dies including the first, second and third dies 100, 200 and 300. In an implementation, the encapsulant 450 also encapsulate the wires (e.g., 411 and 413) as well. As the encapsulant 450, various materials can be employed, for example but not limited to, epoxy, polyimide, etc. Although the wires 411 and 413 are shown as separate wires, they can be a same wire instead in some other implementations.

In some other implementations, the package structure may further include one or more additional dies located between said stack structure of dies and the mounting substrate. Here, taking the at least one third die 300 as shown in FIG. 5A as an example, in the case that the stack structure is comprised of the first die 100 and the second die 200, the third die(s) 300 may be deemed as an additional die outside of the stack structure.

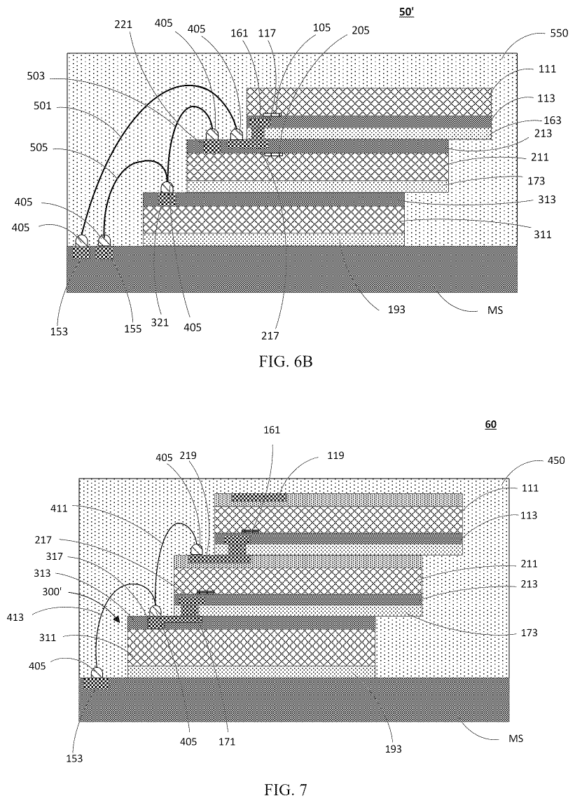

FIG. 6A shows a schematic sectional view of a package structure according to an implementation of the present disclosure. The package structure 50 as shown in FIG. 6A may include a first die 100′, a second die 200′ and a third die 300′ stacked in this order over the mounting substrate MS, the third die 300′ being mounted onto the mounting substrate.

The first die 100′ may be the first die 100′s as above-described in connection with FIG. 3B. The first die 100′ includes a semiconductor substrate 111 and a circuit layer 113 with a coupling component (e.g., pad) 117 formed in or on an insulating layer (not labeled). The coupling component 117 may be coupled in turn to active devices 105. As shown in FIG. 6A, the first die 100′ is disposed such that the first main surface 101 of the first die 100′ faces the second die 200′, and thus facing the mounting substrate MS. Please note that the first die 100′ does not have a RDL on or at its second main surface, and the second surface of the semiconductor substrate (herein, upper surface thereof in FIG. 6A) acts as the second main surface of the first die 100′.

The second die 200′ includes a semiconductor substrate 211 and a circuit layer 213 with a coupling component (e.g., pad) 217 formed in or on an insulating layer (not labeled). In some implementations, the coupling component 217 may be coupled in turn to active devices 205. As shown in FIG. 6A, the second die 200′ is disposed such that the first main surface 201 of the second die 200′ faces the first die 100′. Similarly, in this implementation, the second die 200′ does not have a RDL on or at its second main surface. The second die 200′ may further include a coupling component 221 for wire bonding.

The third die 300′ includes a semiconductor substrate 311 and a circuit layer 313 with a coupling component (e.g., pad) 321 formed in or on an insulating layer (not labeled). In some implementations, the coupling component 321 may provide electrical connection to the semiconductor substrate 311, for example, may be coupled to active devices 305 (if any). As shown in FIG. 6A, the third die 300′ is disposed such that the first main surface 301 of the third die 300′ faces the first die 100′. Similarly, in this implementation, the third die 300′ does not have a RDL on or at its second main surface. The coupling component 321 may be employed for wire bonding.

Although the second and third dies 200′ and 300′ are shown as having no RDL in FIG. 6A, in other implementations, any of the second die 200′ and the third die(s) 300′ may have the RDL on its second surface if needed. In some implementations, at least one of the second die 200′ and the third die(s) 300′ is disposed such that the first main surface 201 or 301 of the respective die faces the first die 100′. In each of the dies, the active devices may be formed, for example, in or on an active surface of the respective semiconductor substrate, which is adjacent to the first main surface. The coupling component 221/321 may be a conductive path providing electrical connection to the devices formed in or on the substrate, for example, be a metal plug, via, contact, pad, etc., or any combination thereof.

As shown in FIG. 6A, the coupling component 117 of the first die 100′ is coupled to the coupling component 217 of the second die 200′, for example, via solder bump or metal pilar 161. Similarly, an insulating bonding layer 163 can be formed between the first die 100 and the second die 200. As an example, the insulating bonding layer 163 may be formed from epoxy, polyimide, etc. The solder bump or metal pillar 161 may be at least partly disposed in the insulating bonding layer 163.

The second die 200′ may be attached to the third die 300′ via an insulating bonding layer 173. The third die 300′ may be attached to the mounting substrate MS, for example, via an insulating bonding layer 193.

FIG. 6B shows a schematic sectional view of a package structure according to an implementation of the present disclosure. In addition to the package structure 50, the package structure 50′ may further comprise wires 501, 503, and 505 and encapsulant 550 which at least encapsulates the stack structure of dies and the wires as well. The wire 501 has an end bonded with the coupling component 153 of the mounting substrate MS and the other end bonded with the coupling component 217 of the second die 200′, for example, via the respective solder bumps or solder pastes 405. The coupling component 217 of the second die 200′ is in turn coupled with the coupling component 117 of the first die 100′ via the solder bump or meal pillar 161. The wire 503 has an end bonded with the coupling component 221 of the second die 200′ and the other end bonded with the coupling component 321 of the third die 300′, which is coupled with the coupling component 155 of the mounting substrate MS, for example, via the respective solder balls or solder pastes 405.

In the implementations of FIGS. 6A and 6B, the first main surfaces (i.e., the main surfaces close to the respective active devices thereof) of the second die 200′ and the third die 300′ face the first die 100′, that is, face away from the mounting substrate MS. However, such implementations are merely illustrative. In other implementations, the second die 200′ and the third die(s) 300′ can be configured differently.

Although FIGS. 5A, 5B, 6A, and 6B each show a package structure including three dies, the package structures according to other implementations may include more dies, for example, N dies, where N is natural number greater than 3, for example, 4, 6, 8 or even more. In such a case, the first die is the furthest die, among all the dies over the mounting substrate, away from the mounting substrate MS, and the Nth die is the closest die to the mounting substrate MS. The Nth die may be mounted onto the mounting substrate MS in the way that the third die 300 or 300′ is mounted onto the mounting substrate MS. And the fourth through (N−1)th dies each can be stacked and coupled between the adjacent dies in a way that the second die 200 or 200′ is stacked and coupled.

FIG. 7 shows a schematic sectional view of a package structure according to an implementation of the present disclosure. The package structure 60 of FIG. 7 differs from the package structure 40′ of FIG. 5B mainly in that the third die 300 of FIG. 5B is replaced with a third die 300′ without the RDL on the second main surface thereof. Those elements which are the same as those shown and depicted in the proceeding figures are indicated with same references, and omitted from being further described in detail. The contents as above described can be adaptably or similarly applied here. Herein, the coupling component 317 is shown as being coupled to the semiconductor substrate and the solder bump/metal pillar 171. However, it should be noted that this is merely illustrative.

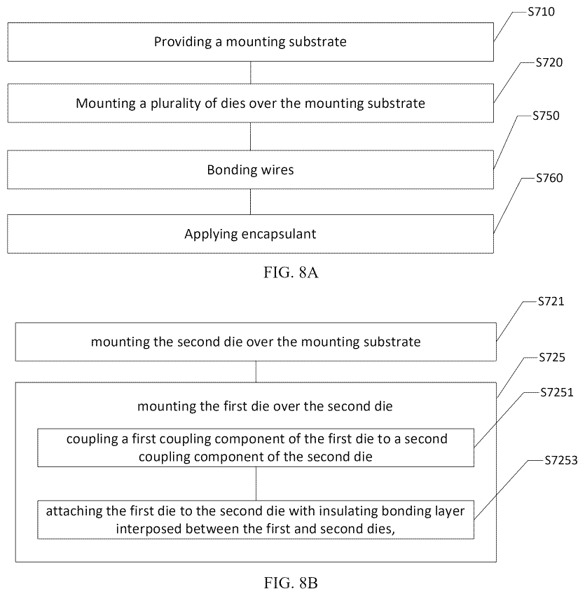

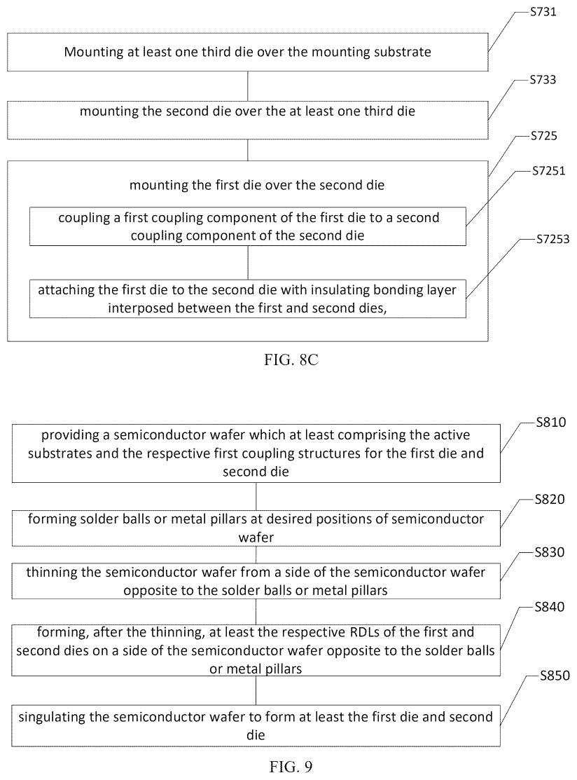

FIG. 8A shows a flow chart of a method of preparing a package structure according to an implementation of the present disclosure. The method may comprise, at step S710, providing a mounting substrate, e.g., the mounting substrate MS as above-mentioned. The method may further comprise, at step S720, mounting a plurality of dies, at least comprising a first die (e.g., the first die 100 or 100′) and a second die (e.g., the second die 200 or 200′), over the mounting substrate with the second die interposed between the first die and the mounting substrate. The first die has a first main surface (e.g., 101) with active devices formed adjacent to the first main surface and an opposite second main surface (e.g., 103). The first die is mounted over the second die with the first main surface of the first die faces towards the second die.

In some implementations, the first die may include a first coupling component (e.g., 117) provided in or on the first main surface, and the second die may include a second coupling component (e.g., 219, FIGS. 2 and 4; 217, FIGS. 5A, 5B, and 6) provided in or on a main surface of the second die facing the first die.

FIG. 8B shows a flow chart of a method of mounting a plurality of dies over the mounting substrate according to another implementation of the present disclosure. As shown in FIG. 8B, in some implementations, mounting the plurality of dies over the mounting substrate may include: at step S721, mounting the second die over the substrate; and at step S725, mounting the first die over the second die with the first main surface of the first die facing towards the second die. Mounting the first die over the second die may include: coupling, at step S7251 the first coupling component of the first die to the second coupling component of the second die, for example, with a solder bump or metal pillar; and attaching, at step S7253, the first die to the second die with insulating bonding layer interposed between the first and second dies.

In some implementations, the plurality of dies may further include at least one third die other than the first and second dies. The first die may include a first coupling component provided in or on the first main surface. The second die may include a second coupling component provided in or on a main surface of the second die facing the first die. FIG. 8C shows a flow chart of a method of mounting a plurality of dies over the mounting substrate according to another implementation of the present disclosure. In some implementations, as shown in FIG. 8C, mounting the plurality of dies over the mounting substrate may include: mounting the at least one third die over the mounting substrate, at a step S731 which may be optional for some implementations; mounting the second die over the at least one third die, at step S733 ; and mounting the first die over the second die, at step S725, with the first main surface of facing towards the second die. In some implementations, mounting the first die over the second die may include: at step S7251, coupling the first coupling component of the first die to the second coupling component of the second die via a solder bump or a metal pillar; and at step S7253, attaching the first die to the second die with insulating bonding layer interposed between the first and second dies. The solder bump or metal pillar may be at least partly disposed in the insulating bonding layer. In some implementations, the insulating bonding layer may be a DAF film.

Now, reference is made back to FIG. 8A. In some implementations, the method may further comprise: at step S750, bonding at least one wire between the second die and the mounting substrate. In some detail implementations, the at least one wire may have one end coupled to the second coupling component of the second die and the other end coupled to the corresponding coupling component of the mounting substrate. The second coupling component of the second die may be coupled to the corresponding coupling component of the first die, for example, via a solder bump or metal pillar.

In some implementations, the method may further comprise: at step S760, applying an encapsulant to at least encapsulate the plurality of dies, and the wire(s) (if any) as well.

In an implementation, the first die is the furthest die of the plurality of dies from the mounting substrate.

In some implementations, the plurality of dies may be substantially the same as each other, and each of the plurality of dies may include a first main surface with active devices formed adjacent to the first main surface and an opposite second main surface, and may include a first coupling structure at the first main surface thereof and a Redistribution Layer (RDL) at the second main surface thereof. The first coupling structure may include a first coupling component provided in or on the first main surface. FIG. 9 shows a flow chart of a method of preparing a package structure according to an implementation of the present disclosure. As shown in FIG. 9, the method may comprise: at step S810, providing a semiconductor wafer which at least comprising semiconductor substrates of and the respective first coupling structures for the first die and the second die. At step S820, solder bumps or metal pillars are formed at desired positions of semiconductor wafer, which are coupled to corresponding first coupling components of the first die and the second die. At step S830, the semiconductor wafer is thinned from a side of the semiconductor wafer opposite to the solder bumps or metal pillars. At step S840, optionally, after the thinning, at least the RDLs of the first and second dies are formed on the side of the semiconductor wafer opposite to the solder bumps or metal pillars. At step S850, the semiconductor wafer is singulated to form dies, for example, the first die, the second die, and/or the third die as above described. Optionally, before singulating, a DAF film may be applied to the wafter on the surface on which the solder bumps or metal pillars are formed. The DAF film may have openings so as to expose the solder bumps or metal pillars. In other implementations, insulating bonding materials can be applied after the coupling of the die onto the mounting substrate or another die. In some implementations, the methods described in connection with FIGS. 8A, 8B, and 8C can be adaptively applied to the singulated dies.

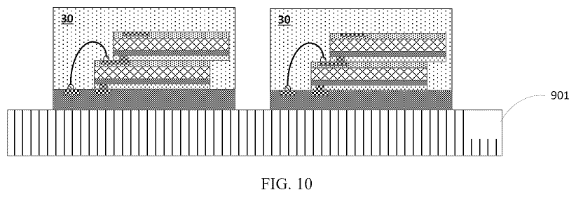

FIG. 10 shows an apparatus comprising a package structure according to an implementation of the present disclosure. As shown in FIG. 10, the apparatus may include a board (e.g., PCB board) 901, and a package structure mounted over the board. The package structure may be the package structure according to any of the implementations of the present disclosure. As an example, two package structures 30 are shown in FIG. 10 as being mounted onto the board 901; however, this is merely illustrative, and various package structures and/or any number of package structures can be employed.

According to the various implementations, with the first main surface of the first die facing the mounting substrate, the strength of the package can be enhanced. This may be because of such a fact that the circuit layer of the die (e.g., the first die) of the stack structure, of which mechanical strength is limited, is prevented from facing external to receive the compress or stress, and instead, a surface of the semiconductor substrate (e.g., silicon) or a dummy layer or buffer layer (e.g., the RDL 215) over the semiconductor substrate is configured to face external to receive the compress or stress. Thus, the mechanical strength of the chip (or die) can be increased.

On the other hand, the active surface, and thus the devices (e.g., active devices) formed on or in the active surface, of the die (e.g., the first die) is away from the second main surface of the respective die, which may receive the compress or stress. Thus, the probability of defects due to the compress or stress in the devices, between the layers or different materials of the circuit layer, or between the circuit layer and the devices can be largely reduced, and thus the disfunction probability of the chip can be reduced, and the robustness and reliability of the package structure can be enhanced.

According to some aspects, with the component(s) 117, 119, 217, 219, 161, 317, 319, 171, and any combination thereof, which may be formed from for example metal, the heat dissipation performance of the package structure can be enhanced. Further, since the component(s) 117, 119, 217, 219, 317, 319, or the like may have relatively large area to, for example, receive the solder bump/metal pillar and/or the bonding wire, the heat dissipation performance of the package structure can be further enhanced. In an implementation, high thermal-conductive material(s) can be employed for the bonding layers so as to further improve heat dissipation.

Also, according to some implementations of the present disclosure, through-silicon via (TSV) can be avoided, large reducing the cost and manufacturing time for the package structure.

In addition, due to the strength of the package structure being enhanced, the height of the encapsulant over the stack structure of dies (e.g., over the first die), can be reduced. And, accordingly the height of the whole package can be reduced.

Those skilled in the art will appreciate that the boundaries between the operations (or steps) described in the above implementations are merely illustrative. Multiple operations may be combined into a single operation, single operation may be distributed in additional operations, and operations may be performed at least partially overlapping in time. Moreover, alternative implementations may include multiple instances of a particular operation, and the order of operations may be altered in various other implementations. However, other modifications, variations, and alternatives are also possible. The specification and drawings are, accordingly, to be regarded in an illustrative rather than a restrictive sense.

Although some specific implementations of the present disclosure have been described in detail by way of example, it should be understood by those skilled in the art that the above examples are for illustration only and are not intended to limit the scope of the present disclosure. The various implementations disclosed herein may be combined arbitrarily without departing from the spirit and scope of the present disclosure. Those skilled in the art will also appreciate that various modifications may be made to the implementations without departing from the scope and spirit of the present disclosure. The scope of the present disclosure is defined by the appended claims.

What is claimed is:

1. A package structure comprising:
a mounting substrate;
a first die disposed above the mounting substrate, the first die comprising a first main surface, a second main surface opposite to the first main surface and an active device formed adjacent to the first main surface; and
a second die interposed between the first die and the mounting substrate,
wherein the first main surface of the first die faces towards the second die.

2. The package structure according to claim 1, wherein
the first die comprises a first coupling component provided in or on the first main surface,
the second die comprises a first main surface, a second main surface opposite to the first main surface and a second coupling component provided in or on one of the first main surface and the second main surface of the second die facing the first die, and
the first coupling component is connected to the second coupling component via a solder bump or a metal pillar.

3. The package structure according to claim 1, further comprising:
an encapsulant at least encapsulating the first die and the second die.

4. The package structure according to claim 1, wherein the first die further comprises:
a Redistribution Layer (RDL) at the second main surface of the first die.

5. The package structure according to claim 2, wherein:
the second die further comprises an active device formed adjacent to the first main surface of the second die,
the first main surface of the second die faces towards the mounting substrate, and
the second coupling component is provided in or on the second main surface of the second die.

6. The package structure according to claim 2, wherein:
the second die further comprises an active device formed adjacent to the first main surface of the second die,
the first main surface of the second die faces towards the first die, and
the second coupling component is provided in or on the first main surface of the second die.

7. The package structure according to claim 2, wherein the second die further comprises a Redistribution Layer (RDL) formed adjacent to the first main surface of the second die and wherein the second coupling component comprises a pad positioned in the Redistribution Layer (RDL).

8. The package structure according to claim 2, further comprising:
a wire having one end coupled to the second coupling component and an other end coupled to the mounting substrate.

9. The package structure according to claim 2, further comprising:
an insulating bonding layer interposed between the first die and the second die,
wherein the solder bump or a metal pillar is at least partly disposed in the insulating bonding layer.

10. The package structure according to claim 1, further comprising:
a stack structure comprising a plurality of dies and disposed over the mounting substrate, and
an encapsulant at least encapsulating the stack structure,
wherein,
each of the plurality of dies comprises a first main surface with an active device formed adjacent to the first main surface and a second main surface opposite to the first main surface,
the plurality of dies at least comprises the first die and the second die and at least a third die,
the first die is a furthest die of the stack structure from the mounting substrate, and the second die is a die immediately adjacent to the first die in the stack structure, and
respective first main surfaces of the plurality of dies face towards the mounting substrate.

11. The package structure according to claim 10, wherein the plurality of dies are substantially the same as each other.

12. The package structure according to claim 1, further comprising:
at least one third die disposed between the second die and the mounting substrate.

13. The package structure according to claim 1, wherein the first die comprises a memory die.

14. An apparatus comprising:
a board; and
a package structure mounted over the board, the package structure comprising:
a mounting substrate;
a first die disposed above the mounting substrate, the first die comprising a first main surface, a second main surface opposite to the first main surface and an active device formed adjacent to the first main surface; and
a second die interposed between the first die and the mounting substrate,
wherein the first main surface of the first die faces towards the second die.

15. A method for preparing a package structure, comprising:
providing a mounting substrate; and
mounting a plurality of dies at least comprising a first die and a second die over the mounting substrate with the second die interposed between the first die and the mounting substrate, the first die comprising a first main surface, a second main surface opposite to the first main surface and an active device formed adjacent to the first main surface,
wherein the first die is mounted over the second die with the first main surface of the first die facing towards the second die.

16. The method according to claim 15, wherein the first die comprises a first coupling component provided in or on the first main surface, and the second die comprises a second coupling component provided in or on a main surface of the second die facing the first die, and
wherein mounting a plurality of dies over the mounting substrate comprises:
mounting the second die over the mounting substrate; and
mounting the first die over the second die with the first main surface of the first die facing towards the second die, including:
coupling the first coupling component of the first die to the second coupling component of the second die; and
attaching the first die to the second die with insulating bonding layer interposed between the first die and the second die.

17. The method according to claim 15, wherein
the plurality of dies further comprises at least one third die,
the first die comprises a first coupling component provided in or on the first main surface,
the second die comprises a second coupling component provided in or on a main surface of the second die facing the first die, and
mounting the plurality of dies over the mounting substrate comprises:
mounting the at least one third die over the mounting substrate;
mounting the second die over the at least one third die; and
mounting the first die over the second die with the first main surface of facing towards the second die, including:
coupling the first coupling component of the first die to the second coupling component of the second die via a solder bump or a metal pillar; and
attaching the first die to the second die with insulating bonding layer interposed between the first die and the second die.

18. The method according to claim 15, further comprising:
bonding at least one wire between the second die and the mounting substrate; and
applying an encapsulant to at least encapsulate the plurality of dies.

19. The method according to claim 15, wherein
the first die is a furthest die of the plurality of dies from the mounting substrate.

20. The method according to claim 15,
wherein each of the plurality of dies comprises a first main surface, a second main surface opposite to the first main surface and an active device formed adjacent to the first main surface, and comprises a first coupling structure at the first main surface thereof and a Redistribution Layer (RDL) at the second main surface thereof, the first coupling structure including a first coupling component provided in or on the first main surface,
the method further comprising:
providing a semiconductor wafer which at least comprises semiconductor substrates of and the respective first coupling structures of the first die and the second die;
forming solder bumps or metal pillars at desired positions of the semiconductor wafer, to be coupled to corresponding first coupling components of the first die and the second die;
thinning the semiconductor wafer from a side of the semiconductor wafer opposite to the solder bumps or metal pillars;
forming, after the thinning, at least the RDLs of the first die and the second die on the side of the semiconductor wafer opposite to the solder bumps or metal pillars; and
singulating the semiconductor wafer to form at least the first die and second die.
